(19) United States
(12) Patent Application Publication
(10) Pub. No.: US 2014/0083760 A1
(43) Pub. Date: Mar. 27, 2014

(54) METHOD FOR PRODUCTION OF SEALED BODY, FRAME-SHAPED SPACER FOR PRODUCTION OF SEALED BODY, SEALED BODY AND ELECTRONIC INSTRUMENT

(71) Applicant: NITTO DENKO CORPORATION, Osaka (JP)

(72) Inventors: Tsuyoshi TORINARI, Osaka (JP); Yuichiro SHISHIDO, Osaka (JP)

(73) Assignee: NITTO DENKO CORPORATION, Osaka (JP)

(21) Appl. No.: 14/025,316

(22) Filed: Sep. 12, 2013

(30) Foreign Application Priority Data
Sep. 13, 2012 (JP) 2012-201797

(51) Int. Cl. H05K 5/06

(52) U.S. Cl. CPC H05K 5/065
USPC 174/521; 428/131; 156/60

(57) ABSTRACT

Provided is a method for production of a sealed body which is capable of improving workability and reducing costs owing to resin-sealing in which a mold is not used, while an electronic instrument obtained has no performance failure and the like. The method for production of a sealed body according to the present invention includes: an adherend providing step of providing an adherend on which at least one electronic component is so mounted as to be displaced from a first main surface; a frame-shaped spacer providing step of providing a frame-shaped spacer having an opening formed at a position corresponding to the electronic component; a step of superimposing the frame-shaped spacer and a lead frame so that the electronic component is accommodated in the opening; a first pressure-bonding step of pressure-bonding a sheet-shaped thermosetting resin composition to a second main surface on a side opposite to the first main surface in a state of superimposing the frame-shaped spacer; a frame-shaped spacer removing step of removing the frame-shaped spacer; and a second pressure-bonding step of pressure-bonding a sheet-shaped thermosetting resin composition, which is the same as or different from the sheet-shaped thermosetting resin composition, to the first main surface so as to embed the electronic component.

### BACKGROUND OF THE INVENTION

1. Field of the Invention

The present invention relates to a method for production of a sealed body, a frame-shaped spacer for production of a sealed body, a sealed body and an electronic instrument.

2. Description of the Related Art

In a process of producing an electronic instrument such as a semiconductor package, resin-sealing is performed for protection of an electronic component mounted on an adherend such as a lead frame, or the like. Resin-sealing is performed by transfer sealing using a powdered thermosetting resin composition, potting using a liquid thermosetting resin composition or the like, and it has been proposed that an electronic component mounted on an adherend is resin-sealed using a sheet-shaped thermosetting resin composition for more easily and conveniently performing resin-sealing (JP-A-8-255806).

In the above-described technique, a mold is used for performing resin-sealing. In this respect, variations of standards for adherends and electronic components are increased with diversification of electronic instruments, but in resin-sealing using a mold as described above, when the form of an adherend or electronic component is changed, the mold must be accordingly changed, so that labor for changing molds and preparation of molds are required to match with various forms. Therefore, use of a mold in resin-sealing makes it difficult to quickly cope with diversification of electronic instruments, and imposes a significant limitation on improvement of workability and improvement in terms of costs in production of electronic instruments.

Thus, the inventors of the present application performed resin-sealing without using a mold, and resultantly found that resin-sealing is possible, but an electronic instrument obtained may not exhibit expected performance in some cases.

An object of the present invention is to provide a method for production of a sealed body which is capable of improving workability and reducing costs owing to resin-sealing in which a mold is not used, while an electronic instrument obtained has no performance failure and the like, a frame-shaped spacer for production of a sealed body, which is used in the production method, a sealed body which is obtained by the production method, and an electronic instrument which is obtained from the sealed body.

### SUMMARY OF THE INVENTION

The inventors of the present application conducted studies on performance failures of electronic instruments, and resultantly found that the structure of an electronic component mounting portion or its vicinity was deformed, and therefore it was thought that due to the deformation, a predetermined effect could not be exhibited. Further studies resulted in the findings that in resin-sealing, the sheet-shaped thermosetting resin composition is softened, but is usually given a predetermined pressure, and therefore when an electronic component is so mounted as to protrude from the surface of an adherend, the pressure is concentrated on the protruded portion, leading to occurrence of deformation. In view of the trend of development of electronic components and adherends, progressive thickness reduction will further reduce mechanical strength, and therefore the need to prevent the above-mentioned deformation may be increasing. Based on the above findings, the inventors of the present application have found that the aforementioned object can be achieved by employing the configuration described below, leading to completion of the present invention.

That is, the present invention is a method for production of a sealed body, including:

an adherend providing step of providing an adherend on which at least one electronic component is so mounted as to be displaced from a first main surface;

a frame-shaped spacer providing step of providing a frame-shaped spacer having an opening formed at a position corresponding to the electronic component;

a step of superimposing the frame-shaped spacer and the adherend so that the electronic component is accommodated in the opening;

a first pressure-bonding step of pressure-bonding a sheet-shaped thermosetting resin composition to a second main surface on a side opposite to the first main surface in a state of superimposing the frame-shaped spacer;

a frame-shaped spacer removing step of removing the frame-shaped spacer; and

a second pressure-bonding step of pressure-bonding a sheet-shaped thermosetting resin composition, which is the same as or different from the sheet-shaped thermosetting resin composition, to the first main surface so as to embed the electronic component.

According to the production method, since the sheet-shaped thermosetting resin composition is pressure-bonded to the second main surface while the electronic component displaced from the first main surface is accommodated in the opening of the frame-shaped spacer, application of the pressure to an electronic component mounting portion can be prevented, and consequently deformation of the structure of the electronic component mounting portion or its vicinity can be prevented. Further, since the electronic component mounting portion is reinforced by pressure bonding of the sheet-shaped thermosetting resin composition to the second main surface, deformation of the mounting portion, or the like can be prevented even when the pressure is applied at the time of resin-sealing of the first main surface. Further, since an electronic component can be resin-sealed merely by using a frame-shaped spacer having a predetermined opening formed therein, the necessity to provide special molds to match with various forms is eliminated, thus making it possible to achieve improvement of workability and cost reduction. In addition, since even when standards of an electronic component and an adherend are changed, it is only necessary to change the thickness and opening position of the frame-shaped spacer according to a mode of mounting the electronic component on the adherend, diversification of electronic instruments can be quickly coped with.

In the production method, preferably at least one of the first pressure-bonding step and the second pressure-bonding step is performed using flat plate press processing. By performing press-bonding using flat plate press processing, pressure application to the whole surface of the sheet-shaped thermosetting resin composition can be performed by one operation, and even when a pressure application state should be retained for a predetermined period of time, the state can be easily retained. Further, when a plurality of electronic components are mounted, pressure bonding of the sheet-shaped thermosetting resin composition to the plurality of electronic components can be performed at a time.

In the production method, preferably the flat plate press processing is performed through a spacer to adjust the thickness of the sheet-shaped thermosetting resin composition. Consequently, the thickness can be adjusted to a desired thickness of a sealed body in the order of a μm unit.

In the production method, preferably at least one of the first pressure-bonding step and the second pressure-bonding step is performed in a reduced-pressure atmosphere. Adhesion of the sheet-shaped thermosetting resin composition to the adherend is improved, so that occurrence of voids between the former and the latter can be suppressed to improve reliability of the sealed body obtained.

In the production method, a plurality of electronic components are mounted on the adherend, and the second pressure-bonding step can be performed so as to embed the plurality of electronic components side by side. Since resin-sealing of a plurality of electronic components is performed at a time, sealed body production efficiency can be significantly enhanced.

The present invention also includes a frame-shaped spacer for production of a sealed body, which is used in the method for production of a sealed body, and has an opening formed at a position corresponding to the electronic component.

The present invention also includes a sealed body which is obtained by the method for production of a sealed body.

Further, the present invention also includes an electronic instrument which is obtained by dicing the sealed body.

### BRIEF DESCRIPTION OF THE DRAWINGS

FIG. 1 is a sectional schematic view illustrating a lead frame on which a semiconductor element is mounted according to one embodiment of the present invention;

FIG. 2 is a perspective view schematically illustrating a frame-shaped spacer according to one embodiment of the present invention;

FIG. 3 is a sectional schematic view illustrating one step of a method for production of a sealed body according to one embodiment of the present invention;

FIG. 4 is a sectional schematic view illustrating one step of a method for production of a sealed body according to one embodiment of the present invention;

FIG. 5 is a sectional schematic view illustrating one step of a method for production of a sealed body according to one embodiment of the present invention;

FIG. 6 is a sectional schematic view illustrating one step of a method for production of a sealed body according to one embodiment of the present invention;

FIG. 7 is a sectional schematic view illustrating a lead frame on which a semiconductor element is mounted according to another embodiment of the present invention; and

FIG. 8 is a sectional schematic view illustrating a lead frame on which a semiconductor element is mounted according to still another embodiment of the present invention.

### DETAILED DESCRIPTION OF THE PREFERRED EMBODIMENTS

A method for production of a sealed body according to the present invention includes: an adherend providing step of providing an adherend on which at least one electronic component is so mounted as to be displaced from a first main surface; a frame-shaped spacer providing step of providing a frame-shaped spacer having an opening formed at a position corresponding to the electronic component; a step of superimposing the frame-shaped spacer and the adherend so that the electronic component is accommodated in the opening; a first pressure-bonding step of pressure-bonding a sheet-shaped thermosetting resin composition to a second main surface on a side opposite to the first main surface in a state of superimposing the frame-shaped spacer; a frame-shaped spacer removing step of removing the frame-shaped spacer; and a second pressure-bonding step of pressure-bonding a sheet-shaped thermosetting resin composition, which is the same as or different from the sheet-shaped thermosetting resin composition, to the first main surface so as to embed the electronic component. Steps according to one embodiment of the present invention will be described below with reference to the drawings.

### First Embodiment

### Adherend Providing Step

In the adherend providing step, an adherend on which at least one electronic component is so mounted as to be displaced from a first main surface is provided. FIG. 1 is a sectional schematic view illustrating a lead frame on which a semiconductor element is mounted according to one embodiment of the present invention. In this embodiment, a lead frame 10 including a plurality of die pads 1 is used as the adherend, and a semiconductor element 3 is used as the electronic component. As the lead frame and semiconductor element, a known lead frame and semiconductor element can be used.

The semiconductor element 3 is mounted on the die pad 1 of the lead frame 10 with an adhesive layer (not illustrated) interposed therebetween, and an electrode (not illustrated) on the upper surface of the semiconductor element 3 and an inner lead 2 are electrically connected by a bonding wire 5. In FIG. 1, the die pad 1 and the semiconductor element 3 are shown one each, but in the lead frame of this embodiment, a semiconductor element is mounted for each of a plurality of die pads. The die pad 1 supported by another inner lead (not illustrated) is provided above a first main surface S1 of the lead frame 10, and similarly the inner lead 2 is provided crookedly so that its tip is located above the first main surface S1 for electrical connection with the semiconductor element 3.

The semiconductor element 3 is so mounted as to be displaced from the first main surface S1 of the lead frame 10 as illustrated in FIG. 1. Specifically, the semiconductor element 3 is mounted on the die pad 1 such that its upper surface is displaced upward by an amount equivalent to a height h from the first main surface S1. The height h is determined according to the specification of an intended semiconductor package. From the viewpoint of the whole of the lead frame 10, a portion of the inner lead 2 extending from the bent portion from the first main surface S1 to the tip, the die pad 1, the semiconductor element 3 and the bonding wire 5 are so arranged as to be displaced upward with respect to the first main surface S1.

### Frame-Shaped Spacer Providing Step

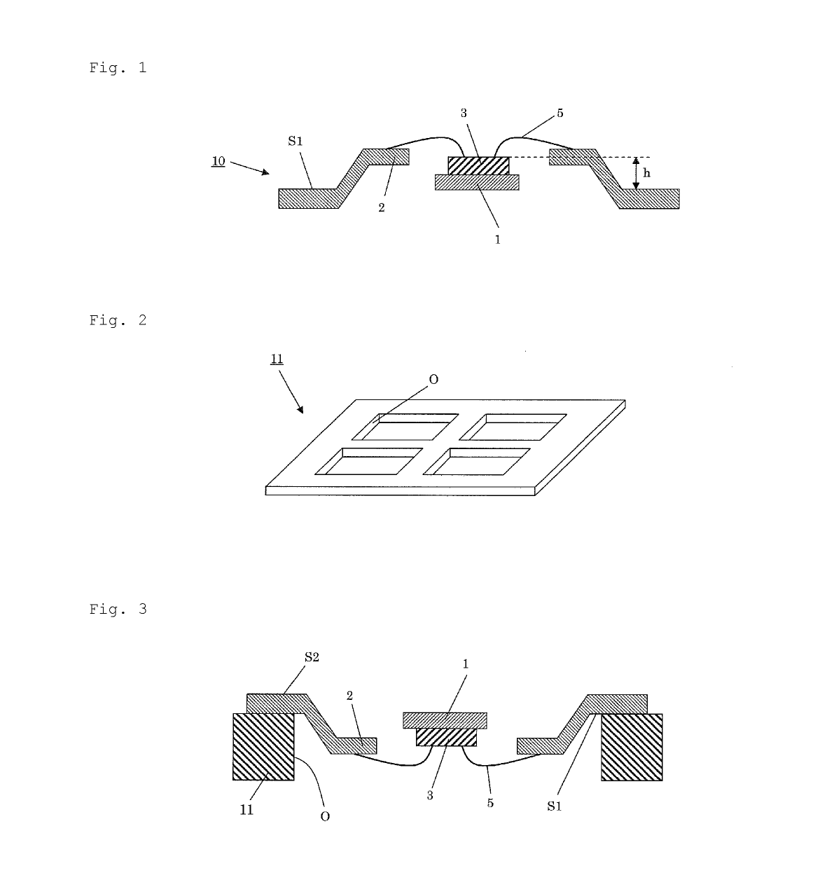

In the frame-shaped spacer providing step, a frame-shaped spacer having an opening formed at a position corresponding to an electronic component is provided. FIG. 2 is a perspective view schematically illustrating a frame-shaped spacer according to one embodiment of the present invention. In the frame-shaped spacer 11, four openings O are formed. The opening O is formed at a position corresponding to the semiconductor element 3 so that the semiconductor element 3 can be accommodated when the frame-shaped spacer 11 is superimposed on the first main surface S1 of the lead frame as described later. The number and shape of openings O may be set in accordance with the number and shape of semiconductor elements 3 so arranged as to be displaced from the first main surface S1, inner leads 2 for supporting the semiconductor elements, and the like. The depth of the opening O (i.e. thickness of frame-shaped spacer 11) may also be determined with consideration given to the height (displacement) of the portion that protrudes farthest from the first main surface S1.

The material of the frame-shaped spacer 11 is not particularly limited as long as it has strength and heat resistance against pressure and heating at the time when the sheet-shaped thermosetting resin composition is pressure-bonded to the lead frame 10. The surface of the frame-shaped spacer 11 may be subjected to a mold release treatment so that when the frame-shaped spacer 11 is removed, it is easily separated from the lead frame 10. When strength, heat resistance and mold releasability are considered, Teflon (registered trademark) can be suitably used as an exemplary constituent material.

### Frame-Shaped Spacer Superimposing Step

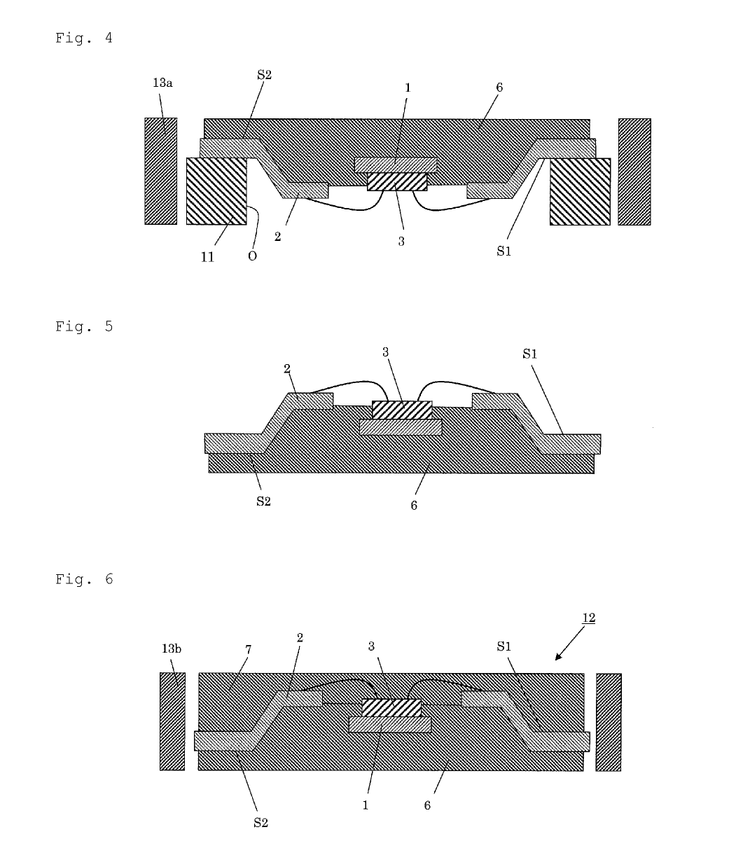

In this step, the frame-shaped spacer and the lead frame are superimposed on each other so that the electronic component is accommodated in the opening of the frame-shaped spacer. As illustrated in FIG. 3, a plurality of openings O are formed so as to match with semiconductor elements 3, and therefore when the frame-shaped spacer 11 and the lead frame 10 are superimposed on each other, each semiconductor element 3 is accommodated in the corresponding opening O. Further, the die pad 1, the inner lead 2 and the bonding wire 5 are also accommodated in the opening O together with the semiconductor element 3.

The frame-shaped spacer 11 is superimposed in contact with the first main surface S1 of the lead frame. For the arrangement relation between the frame-shaped spacer 11 and the lead frame, preferably the frame-shaped spacer 11 is situated on the lower side and the lead frame is arranged thereon so that pressure bonding of the sheet-shaped thermosetting resin composition is facilitated in a subsequent first pressure-bonding step. In this case, a second main surface S2 on a side opposite to the first main surface S1 of the lead frame faces upward.

### First Pressure-Bonding Step

In the first pressure-bonding step, a sheet-shaped thermosetting resin composition 6 is pressure-bonded to the second main surface S2 on a side opposite to the first main surface S1 in a state of superimposing the frame-shaped spacer 11 as illustrated in FIG. 4. Consequently, the lead frame is resin-sealed on the second main surface S2 side including regions on the back sides of the die pad 1 and the inner lead 2. At this time, the semiconductor element 3 and its peripheral structure are accommodated in the opening O, and therefore even when pressing is performed for pressure bonding, the pressure is not concentrated on portions displaced from the first main surface S1 and as a result, deformation and collapse of the displaced portions can be prevented.

The size of the sheet-shaped thermosetting resin composition 6 in plan view is preferably such a size that all of a plurality of semiconductor elements 3 can be covered with one sheet-shaped thermosetting resin composition to seal the plurality of semiconductor elements 3 at a time. Of course, the sheet-shaped thermosetting resin composition cut into the same number of pieces as semiconductor elements to be sealed may be provided, and used for resin-sealing.

Considering workability, followability of the sheet-shaped thermosetting resin composition to unevenness of the lead frame, and adhesion at the time of the press-bonding, the viscosity of the sheet-shaped thermosetting resin composition at 90° C. (90 to 110° C.) is preferably 1500 to 3000 Pa·s. The viscoelasticity can be measured in accordance with the following procedure. A sheet-shaped thermosetting resin composition prepared is measured using a viscoelasticity measuring device (manufactured by TA Instruments Japan Inc.: Model ARES). Specifically, the viscoelasticity can be obtained as follows: a measurement sample is prepared by forming a sheet-shaped thermosetting resin composition before curing treatment into a disc shape having a diameter of 8 mm and a thickness of 1 mm, and set on a fixture for a measuring device, a viscosity at 40 to 150° C. is measured under conditions including a frequency of 1 Hz and a temperature rising rate of 10° C./min, and a viscosity (Pa·s) at 90 to 110° C. is read from the obtained data.

### (Sheet-Shaped Thermosetting Resin Composition)

Components of the sheet-shaped thermosetting resin composition are not particularly limited as long as the sheet-shaped thermosetting resin composition is in a softened state at room temperature or during heating so as to be followable to the uneven structure of the lead frame at the time of press-bonding, and is cured by a subsequent heat curing treatment, so that the semiconductor element can be sealed. Examples of typical components include an epoxy resin and a phenol resin, and a thermoplastic resin and the like are added thereto as required.

Examples of the sheet-shaped thermosetting resin composition suitable for this embodiment include those containing the following components A to E with the content of the component C being 15 to 30% by weight with respect to the total sheet-shaped thermosetting resin composition.

A: Epoxy resin containing an acetal group
B: Phenol resin

### C: Elastomer

D: Inorganic filler
E: Imidazole compound

### (Component A)

The epoxy resin containing an acetal group (component A) is not particularly limited as long as it is an epoxy resin containing an acetal group. For example, those obtained by introducing an acetal group into various kinds of epoxy resins, such as a modified bisphenol A type epoxy resin, a modified bisphenol F type epoxy resin, a bisphenol A type epoxy resin, a bisphenol F type epoxy resin, a triphenylmethane type epoxy resin, a dicyclopentadiene type epoxy resin, a cresol novolac type epoxy resin, a phenol novolac type epoxy resin, a biphenyl type epoxy resin and a phenoxy resin, can be used. These epoxy resins may be used alone or used in combination of two or more thereof. Particularly, use of a modified bisphenol A type epoxy resin having an acetal group is preferred because it is liquid, and therefore easy to handle. An epoxy resin containing an acetal group (component A) and an epoxy resin not containing an acetal group may be used in combination.

The epoxy resin that is used in combination with the epoxy resin containing an acetal group (component A) is not particularly limited. For example, various kinds of epoxy resins such as a triphenylmethane type epoxy resin, a dicyclopentadiene type epoxy resin, a cresol novolac type epoxy resin, a phenol novolac type epoxy resin, a bisphenol A type epoxy resin, a bisphenol F type epoxy resin, a modified bisphenol A type epoxy resin, a modified bisphenol F type epoxy resin, a biphenyl type epoxy resin and a phenoxy resin can be used.

The content of the epoxy resin containing an acetal group (component A) is preferably 3 to 10% by weight with respect to the total sheet-shaped thermosetting resin composition. This is because when the content is less than 3% by weight, it may be difficult to achieve flexibility of the sheet-shaped thermosetting resin composition, and when the content is more than 10% by weight, resin flash, adhesive residue of a dicing tape or the like may occur in dicing after resin-sealing.

### (Component B)

The phenol resin (component B) is not particularly limited as long as it generates a curing reaction with the epoxy resin containing an acetal group (component A). For example, a dicyclopentadiene type phenol resin, a novolac type phenol resin, a cresol novolac resin, a phenol aralkyl resin and the like are used. These phenol resins may be used alone or used in combination of two or more thereof. As the phenol resin (component B), use of those having a hydroxyl group equivalent of 70 to 250 and a softening point of 50 to 110° C. is preferred, and particularly a novolac type phenol resin can be suitably used because it has high curing reactivity. Further, those having low hygroscopicity, such as a phenol aralkyl resin and a biphenyl aralkyl resin, can be suitably used from the viewpoint of reliability.

For the compounding ratio of the epoxy resin containing an acetal group (component A) and the phenol resin (component B), they are compounded so that the total of hydroxyl groups in the phenol resin (component B) is preferably 0.7 to 1.5 equivalents, more preferably 0.9 to 1.2 equivalents, based on 1 equivalent of epoxy groups in the epoxy resin containing an acetal group (component A).

### (Component C)

The elastomer (component C) that is used along with the epoxy resin containing an acetal group (component A) and the phenol resin (component B) is not particularly limited in terms of its structure as long as it imparts plasticity and flexibility to the sheet-shaped thermosetting resin composition, and exhibits such an effect. For example, various kinds of acryl-based copolymers such as a polyacrylic acid ester, and rubbery polymers such as a styrene acrylate-based copolymer, a butadiene rubber, a styrene-butadiene rubber (SBR), an ethylene-vinyl acetate copolymer (EVA), an isoprene rubber and an acrylonitrile rubber can be used. Particularly, use of an acryl-based copolymer is preferred because it is easily dispersed in the epoxy resin (component A), and has high reactivity with the epoxy resin (component A), so that heat resistance and strength of the sheet-shaped thermosetting resin composition obtained can be enhanced. They may be used alone, or used in combination of two or more thereof.

The acryl-based copolymer can be synthesized by, for example, radically polymerizing an acryl monomer mixture having a predetermined mixing ratio using a usual method. As a method for radical polymerization, a solution polymerization method using an organic solvent as a solvent, or a suspension polymerization method of performing polymerization while dispersing a raw material monomer in water is used. Examples of the polymerization initiator that is used at this time include 2,2′-azobisisobutyronitrile, 2,2′-azobis-(2,4-dimethylvaleronitrile), 2,2′-azobis-4-methoxy-2,4-dimethylvaleronitrile, other azo-based or diazo-based polymerization initiators, and peroxide-based polymerization initiators such as benzoyl peroxide and methyl ethyl ketone peroxide. In the case of suspension polymerization, it is desirable to add a dispersant such as, for example, polyacrylamide or polyvinyl alcohol.

The content of the elastomer (component C) is preferably 15 to 30% by weight with respect to the total sheet-shaped thermosetting resin composition. When the content of the elastomer (component C) is less than 15% by weight, it is difficult to achieve plasticity and flexibility of the sheet-shaped thermosetting resin composition, and it is also difficult to perform resin-sealing while warpage of the lead frame is suppressed. When conversely the content is more than 30% by weight, a gap between the semiconductor element and the lead frame may be hard to be filled with a resin because the melt viscosity of the sheet-shaped thermosetting resin composition is increased, and the strength and heat resistance of a cured product of the sheet-shaped thermosetting resin composition may be reduced.

Preferably, the weight ratio of the elastomer (component C) to the epoxy resin containing an acetal group (component A) (weight of component C/weight of component A) is set to 3 to 4.7. This is because when the weight ratio is less than 3, it may be difficult to control the fluidity of the sheet-shaped thermosetting resin composition, and when the weight ratio is more than 4.7, tackiness of the sheet-shaped thermosetting resin composition to the lead frame may be poor.

### (Component D)

The inorganic filler (component D) is not particularly limited, and various kinds of previously known fillers can be used. Examples thereof include powders of quartz glass, talk, silica (fused silica, crystalline silica, etc.), alumina, aluminum nitride, silicon nitride and the like. They may be used alone, or used in combination of two or more thereof.

Particularly, because the thermal linear expansion coefficient of the cured product of the sheet-shaped thermosetting resin composition is reduced, leading to a reduction in internal stress, and resultantly warpage of the lead frame after sealing can be suppressed, use of a silica powder is preferred, and among silica powders, use of a fused silica powder is more preferred. Examples of the fused silica powder include a spherical fused silica powder and a crushed fused silica powder, and use of a spherical fused silica powder is especially preferred from the viewpoint of fluidity. Particularly, use of those having an average particle diameter of 0.1 to 70 μm is preferred, and use of those having an average particle diameter of 0.3 to 55 μm is especially preferred. The average particle diameter can be derived by randomly extracting samples from a population and measuring the samples using a laser diffraction/scattering grain size distribution measuring device.

The content of the inorganic filler (component D) is preferably 50 to 90% by weight, more preferably 80 to 90% by weight, further preferably 80 to 88% by weight with respect to the total sheet-shaped thermosetting resin composition. That is, when the content of the inorganic filler (component D) is less than 50% by weight, warpage of the sealed body may be increased because the linear expansion coefficient of the sealed body is increased. On the other hand, when the content is more than 80% by weight, tackiness to the semiconductor element and the lead frame may be reduced because plasticity and fluidity of the sheet-shaped thermosetting resin composition are deteriorated.

### (Component E)

The imidazole compound (component E) is not particularly limited as long as it accelerates a curing reaction of the epoxy resin containing an acetal group (component A) and the phenol resin (component B), and besides the imidazole compound, an acid adduct thereof may be used. They may be used alone, or used in combination of two or more thereof. By using the imidazole compound (compound E), resin-sealing can be performed at a relatively low temperature, and resin-sealing can be performed while warpage of the lead frame is suppressed. Particularly, an imidazole compound represented by the following formula (1) is preferably used from the viewpoint of storage stability of the sheet-shaped thermosetting resin composition.

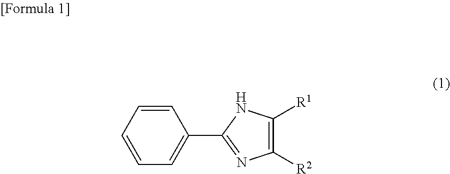

In the formula, R¹ and R² are each independently an alkyl group or an alkylol group, and at least one thereof is an alkylol group.

The content of the imidazole compound (component E) is preferably 0.1 to 10% by weight, more preferably 0.3 to 3% by weight, further preferably 0.5 to 2% by weight with respect to the total sheet-shaped thermosetting resin composition. This is because when the content is less than 0.1% by weight, the curing reaction may be very hard to proceed, and when the content is more than 10% by weight, the curing reaction may proceed even at a low temperature, leading to deterioration of storage stability of the sheet-shaped thermosetting resin composition.

### (Method for Production of Sheet-Shaped Thermosetting Resin Composition)

For example, the sheet-shaped thermosetting resin composition of this embodiment can be produced in the following manner. First, a sheet-shaped thermosetting resin composition is prepared by mixing compounding components, and the method thereof is not particularly limited as long as the compounding components are uniformly dispersed and mixed. The compounding components are dissolved or dispersed in an organic solvent or the like as required, and a film is formed by varnish coating. Alternatively, a film may be formed by directly kneading the compounding components by a kneader or the like to thereby prepare a solid resin composition, and extruding the solid resin composition thus obtained into a sheet shape. As the above-mentioned kneader, for example, a kneader can be suitably used, which includes a kneading screw having, a portion where in a part of a shaft direction, the protrusion amount of a screw blade from a screw shaft is smaller than the protrusion amount of a screw blade from a screw shaft in other portions, or a kneading screw having, in a part of a shaft direction, no screw blade. In the portion where the protrusion amount of a screw blade is small or the portion having no screw blade, the shearing force and stirring level are lowered, and consequently the compression ratio of a kneaded product is increased, so that entrapped air can be removed, thus making it possible to suppress generation of pores in the kneaded product obtained.

Preparation of the sheet-shaped thermosetting resin composition of this embodiment by a varnish coating method will be described. The varnish coating method is preferred because a sheet having a uniform thickness can be easily and conveniently obtained. That is, the components A to E and other additives as required are appropriately mixed in accordance with a usual method, and the mixture is uniformly dissolved or dispersed in an organic solvent to prepare a varnish. Then, the obtained varnish is applied onto a base material of polyester or the like and dried, whereby a sheet-shaped thermosetting resin composition can be obtained. As required, a film such as a polyester film may be laminated for protecting the surface of the sheet. The base material of polyester or the like and the film such as a polyester film are peeled off during resin-sealing.

The organic solvent is not particularly limited, and previously known various kinds of organic solvents, for example, methyl ethyl ketone, acetone, dioxane, diethyl ketone, toluene, ethyl acetate and the like can be used. They may be used alone, or used in combination of two or more thereof. Usually, it is preferred to use the organic solvent so that the solid concentration of the varnish is 30 to 60% by weight.

The thickness of the sheet after drying the organic solvent is not particularly limited, but is usually set at preferably 5 to 100 μm, more preferably 20 to 70 μm from the viewpoint of uniformity of thickness, the amount of a residual solvent and embedment of the semiconductor element 3. As required, the sheet-shaped thermosetting resin composition thus obtained may be laminated to one another so as to have a desired thickness, and used. That is, the sheet-shaped thermosetting resin composition may be used in a single-layer structure, or used as a laminate formed by laminating the sheet into a multilayer structure of two or more layers.

As conditions for the pressure bonding, for example, flat plate pressing is performed at a temperature of 70 to 120° C. and a pressure of 100 to 500 kPa for 0.5 to 5 minutes, the pressure of flat plate pressing is then released, and heating is performed at a temperature of 150 to 190° C. for 30 to 120 minutes to cure the sheet-shaped thermosetting resin composition. By flat plate pressing, pressure application to the whole surface of the sheet-shaped thermosetting resin composition can be performed by one operation, and even when a pressure application state should be retained for a predetermined period of time, the state can be easily retained. Further, when a plurality of semiconductor elements are mounted, pressure bonding of the sheet-shaped thermosetting resin composition to the plurality of semiconductor elements can be performed at a time by changing the size of the pressing flat plate.

From the viewpoint of followability of the sheet-shaped thermosetting resin composition to uneven shapes of the semiconductor element and the lead frame, it is preferred to perform the above-described pressing under a reduced-pressure atmosphere, and the reduced-pressure degree at this time is preferably 50 to 1000 Pa.

In this pressure-bonding step, it is preferred to perform flat plate press processing through a spacer 13a as illustrated in FIG. 4 for adjusting the thickness of the sheet-shaped thermosetting resin composition and hence the thickness of a sealed body obtained to a desired value.

### Frame-Shaped Spacer Removing Step

In this step, the frame-shaped spacer superimposed on the lead frame is removed as illustrated in FIG. 5. At this time, preferably the sheet-shaped thermosetting resin composition 6 is situated on the lower side, and the first main surface S1 of the lead frame is made to face upward so that pressure bonding of a sheet-shaped thermosetting resin composition in the subsequent second pressure-bonding step is facilitated.

### Second Pressure-Bonding Step

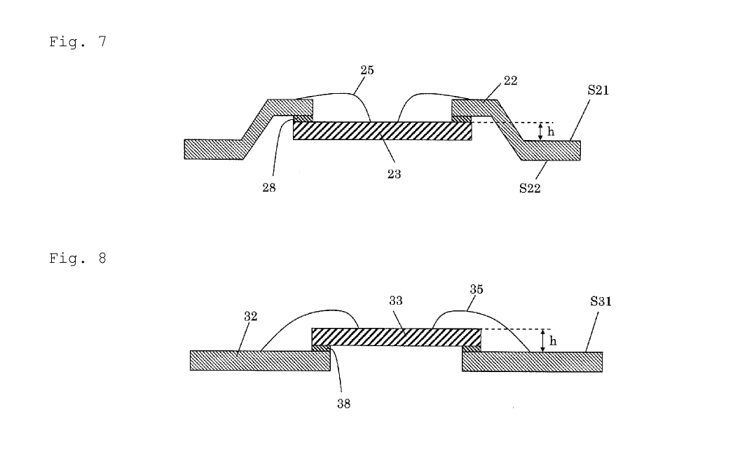

In the second pressure-bonding step, a sheet-shaped thermosetting resin composition 7, which is the same as or different from the above-described sheet-shaped thermosetting resin composition, is press-bonded to the first main surface S1 of the lead frame so as to embed the semiconductor element 3 as illustrated in FIG. 6. By passing through the second pressure-bonding step, the first main surface S1 side of the lead frame including protruding structures from the first main surface S1, such as the inner lead 2 and the bonding wire 5, is resin-sealed together with the semiconductor element 3. In the lead frame of this embodiment, a gap exists between the die pad 1 and the inner lead 2, but the gap can be filled by pressure-bonding the sheet-shaped thermosetting resin compositions 6 and 7 from both surface sides of the lead frame. As pressure-bonding conditions, conditions similar to those in the first pressure-bonding step can be employed.

In the second pressure-bonding step, a sheet-shaped thermosetting resin composition which is the same as the sheet-shaped thermosetting resin composition in the first pressure-bonding step may be used, or a sheet-shaped thermosetting resin composition which is different therefrom may be used. From the viewpoint of a sealing property at the time of performing resin-sealing from both surfaces of the lead frame, use of the same sheet-shaped thermosetting resin composition is preferred because affinity with the sheet-shaped thermosetting resin composition 6 sealing the second main surface S2 side is improved to achieve a good sealing property.

In this pressure-bonding step, it is also preferred to perform flat plate press processing through a spacer 13b as illustrated in FIG. 6 for adjusting the thickness of the sheet-shaped thermosetting resin composition and hence the thickness of a sealed body 12 obtained to a desired value.

By passing through the steps described above, the sealed body 12 according to this embodiment can be suitably produced. In the method for production of a sealed body in this embodiment, a mold for resin-sealing is not needed, but it is only necessary to use a frame-shaped spacer having a simple structure, and therefore improvement of workability and cost reduction in production of a sealed body can be easily achieved. Since concentration of pressure on protruding portions such as a semiconductor element on the lead frame can be prevented at the time of resin-sealing using a sheet-shaped thermosetting resin composition, the semiconductor element 3, its peripheral structure and the like are free from deformation and collapse, so that the sealed body 12 having high reliability can be produced.

### Dicing Step

In this embodiment, the sealed body 12 is then diced to prepare a semiconductor package (not illustrated). Dicing can be performed by fixing the sealed body 12 by a dicing tape and dividing the sealed body 12 into pieces using a dicing device. For the dicing tape and dicing device, a previously known dicing tape and a previously known dicing device can be used.

### Second Embodiment

In the first embodiment, a lead frame including a die pad is used, but in the second embodiment a sealed body is prepared using a lead frame which does not include a die pad. Otherwise procedures similar to those in the first embodiment can be carried out to produce a desired sealed body.

As illustrated in FIG. 7, an inner lead 22 is provided crookedly so that its tip is located above a first main surface S21 for electrical connection to a semiconductor element 23. The semiconductor element 23 is mounted on a lead frame by supporting and fixing the upper surface of the semiconductor element 23 on the lower side of the tip of the inner lead 22 (second main surface S22 side) with a double-sided pressure-sensitive adhesive tape 28 or an adhesive layer interposed therebetween. An electrode (not illustrated) on the upper surface of the semiconductor element 23 and the inner lead 22 are electrically connected by a bonding wire 25.

The semiconductor element 23 is so mounted as to be displaced from the first main surface S21 of the lead frame as illustrated in FIG. 7. Specifically, the semiconductor element 23 is fixed to the inner lead 22 such that its upper surface is displaced upward by an amount equivalent to a height h from the first main surface S21. The height h is determined according to the specification of an intended semiconductor package. From the viewpoint of the whole of the lead frame, a portion of the inner lead 22 extending from the bent portion from the first main surface S21 to the tip, the semiconductor element 23 and the bonding wire 25 are so arranged as to be displaced upward with respect to the first main surface S21.

### Third Embodiment

In the first embodiment, an example is shown in which a semiconductor element is mounted on a die pad displaced from a first main surface of a lead frame, but in the third embodiment, a sealed body is produced using a lead frame which has no die pad and in which an inner lead is not bent but flat. Otherwise procedures similar to those in the first embodiment can be carried out to produce a desired sealed body. As illustrated in FIG. 8, a semiconductor element 33 is mounted on a flat inner lead 32 with a double-sided pressure-sensitive adhesive tape 38 or an adhesive layer interposed therebetween. The semiconductor element 33 is so mounted as to be displaced from a first main surface S31 of the lead frame. Specifically, the semiconductor element 33 is fixed to the inner lead 32 such that its upper surface is displaced upward by an amount equivalent to a height h from the first main surface S31. The height h is determined according to the specification of an intended semiconductor package. From the viewpoint of the whole of the lead frame, the semiconductor element 33 and a bonding wire 35 are so arranged as to be displaced upward with respect to the first main surface S31.

### Fourth Embodiment

In the first embodiment, a sheet-shaped thermosetting resin composition which is the same as that in the first pressure-bonding step is used in the second pressure-bonding step, but in the fourth embodiment, a sheet-shaped thermosetting resin composition which is different from that in the first pressure-bonding step is used in the second pressure-bonding step. Otherwise the procedures of the first embodiment can be employed.

Examples of the sheet-shaped thermosetting resin composition suitably used in the second pressure-bonding step in this embodiment include a sheet-shaped thermosetting resin composition which contains the following components A to F and in which the total content of components E and F is 70 to 90% by weight with respect to the total sheet-shaped thermosetting resin composition.

A: Epoxy resin
B: Phenol resin

### C: Elastomer

D: Curing accelerator
E: Metal hydroxide
F: Phosphazene compound represented by the following formula (1) or (2)

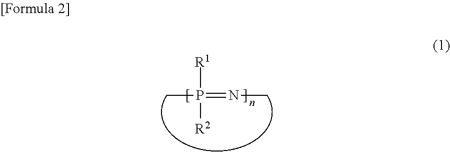

In the formula, n is an integer of 3 to 25, and R¹ and R² may be the same or independent of each other, and are each a monovalent organic group having a functional group selected from the group consisting of an alkoxy group, a phenoxy group, an amino group, a hydroxyl group and an allyl group.

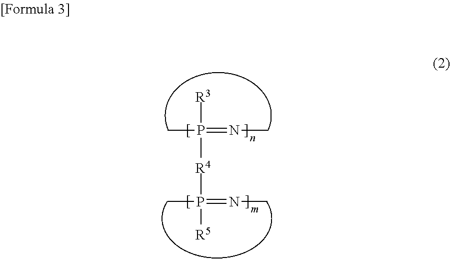

In the formula, n and m may be the same or independent of each other, and are each an integer of 3 to 25; R³ and R⁵ may be the same or independent of each other, and are each a monovalent organic group having a functional group selected from the group consisting of an alkoxy group, a phenoxy group, an amino group, a hydroxyl group and an allyl group; and R⁴ is a divalent organic group having a functional group selected from the group consisting of an alkoxy group, a phenoxy group, an amino group, a hydroxyl group and an allyl group.

### (Component A)

The epoxy resin (component A) is not particularly limited. For example, various kinds of epoxy resins such as a triphenylmethane type epoxy resin, a cresol novolac type epoxy resin, a biphenyl type epoxy resin, a modified bisphenol A type epoxy resin, a bisphenol A type epoxy resin, a bisphenol F type epoxy resin, a modified bisphenol F type epoxy resin, a dicyclopentadiene type epoxy resin, a phenol novolac type epoxy resin and a phenoxy resin can be used. These epoxy resins may be used alone or used in combination of two or more thereof. From the viewpoint of securing toughness of the epoxy resin after curing and reactivity of the epoxy resin, epoxy resins, which have an epoxy equivalent of 150 to 250 and a softening point or melting point of 50 to 130° C., and are solid at normal temperature, are preferred and particularly, a triphenylmethane type epoxy resin, a cresol novolac type epoxy resin and a biphenyl type epoxy resin are preferred from the viewpoint of reliability. From the viewpoint of a low stress property, a modified bisphenol A type epoxy resin having a flexible backbone such as an acetal group or a polyoxyalkylene group is preferred, and a modified bisphenol A type epoxy resin having an acetal group can be particularly suitably used because it is liquid and easy to handle.

Preferably the content of the epoxy resin (component A) is set to 1 to 10% by weight with respect to the total sheet-shaped thermosetting resin composition.

### (Component B)

The phenol resin (component B) is not particularly limited as long as it generates a curing reaction with the epoxy resin (component A). For example, a phenol novolac resin, a phenol aralkyl resin, a biphenyl aralkyl resin, a dicyclopentadiene type phenol resin, a cresol novolac resin, a resol resin and the like are used. These phenol resins may be used alone or used in combination of two or more thereof. As the phenol resin, use of those having a hydroxyl group equivalent of 70 to 250 and a softening point of 50 to 110° C. is preferred from the viewpoint of reactivity with the epoxy resin (component A), and particularly a phenol novolac resin can be suitably used because it has high curing reactivity. Further, those having low hygroscopicity, such as a phenol aralkyl resin and a biphenyl aralkyl resin, can also be suitably used from the viewpoint of reliability.

For the compounding ratio of the epoxy resin (component A) and the phenol resin (component B), they are compounded so that the total of hydroxyl groups in the phenol resin (component B) is preferably 0.7 to 1.5 equivalents, more preferably 0.9 to 1.2 equivalents based on 1 equivalent of epoxy groups in the epoxy resin (component A) from the viewpoint of curing reactivity.

### (Component C)

The elastomer (component C) that is used along with the epoxy resin (component A) and the phenol resin (component B) is not particularly limited in terms of its structure as long as it imparts flexibility required for sheet sealing to the sheet-shaped thermosetting resin composition, and exhibits such an effect. For example, various kinds of acryl-based copolymers such as a polyacrylic acid ester, and rubbery polymers such as a styrene acrylate-based copolymer, a butadiene rubber, a styrene-butadiene rubber (SBR), an ethylene-vinyl acetate copolymer (EVA), an isoprene rubber and an acrylonitrile rubber can be used. Particularly, use of an acryl-based copolymer is preferred because it is easily dispersed in the epoxy resin (component A), and has high reactivity with the epoxy resin (component A), so that heat resistance and strength of the sheet-shaped thermosetting resin composition obtained can be enhanced. They may be used alone, or used in combination of two or more thereof. The acryl-based copolymer can be synthesized by, for example, radically polymerizing an acryl monomer mixture having a predetermined mixing ratio using a usual method. As a method for radical polymerization, a solution polymerization method using an organic solvent as a solvent, or a suspension polymerization method of performing polymerization while dispersing a raw material monomer in water is used.

Preferably the content of the elastomer (component C) is set to 10 to 25% by weight with respect to the total sheet-shaped thermosetting resin composition. That is, when the content of the elastomer (component C) is less than 10% by weight, it is difficult to achieve flexibility sufficient for sheet sealing. When the content is more than 25% by weight, it may be difficult to achieve flame retardancy of the sheet-shaped thermosetting resin composition, and the strength of a cured product of the sheet-shaped thermosetting resin composition may be reduced, so that reliability of a sealed body and a semiconductor package obtained therefrom may be impaired.

### (Component D)

The curing accelerator (component D) is not particularly limited as long as it enhances curing of the epoxy resin and the phenol resin, but from the viewpoint of curability and preservation quality, organic phosphorus-based compounds such as triphenyl phosphine and tetraphenylphosphonium tetraphenylborate, and imidazole-based compounds are suitably used. These curing accelerators may be used alone, or used in combination with other curing accelerators.

### (Component E)

The metal hydroxide (component E) is used as a flame retardant. As the metal hydroxide (component E), various kinds of metal hydroxides such as aluminum hydroxide, magnesium hydroxide, iron hydroxide, calcium hydroxide, tin hydroxide and a composite metal hydroxide can be used. Use of aluminum hydroxide or magnesium hydroxide is preferred, especially use of aluminum hydroxide is preferred, because flame retardancy can be exhibited with a relatively small added amount and in terms of costs. The average particle diameter of the metal hydroxide (component E) is preferably 1 to 10 μm, further preferably 2 to 5 μm, from the viewpoint of securing appropriate fluidity when the sheet-shaped thermosetting resin composition is heated. When the average particle diameter of the metal hydroxide (component E) is less than 1 μm, it may be difficult to uniformly disperse the metal hydroxide in the sheet-shaped thermosetting resin composition, and fluidity may not be sufficiently achieved during heating of the sheet-shaped thermosetting resin composition. When the average particle diameter is more than 10 μm, the flame retardant effect may be deteriorated because the surface area per added amount of the metal hydroxide (component E) decreases.

### (Component F)

The phosphazene compound (component F) is a phosphazene compound represented by the following formula (1) or (2).

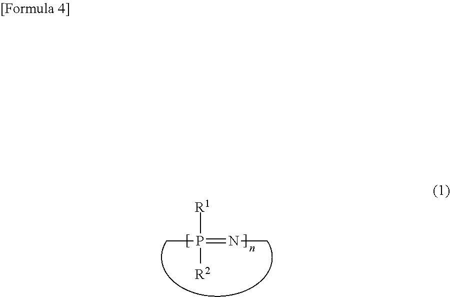

In the formula, n is an integer of 3 to 25, and R¹ and R² may be the same or independent of each other, and are each a monovalent organic group having a functional group selected from the group consisting of an alkoxy group, a phenoxy group, an amino group, a hydroxyl group and an allyl group.

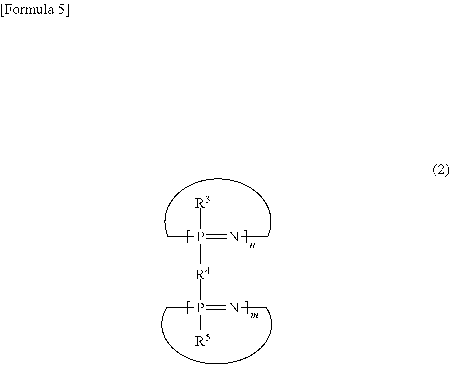

In the formula, n and m may be the same or independent of each other, and are each an integer of 3 to 25; R³ and R⁵ may be the same or independent of each other, and are each a monovalent organic group having a functional group selected from the group consisting of an alkoxy group, a phenoxy group, an amino group, a hydroxyl group and an allyl group; and R⁴ is a divalent organic group having a functional group selected from the group consisting of an alkoxy group, a phenoxy group, an amino group, a hydroxyl group and an allyl group.

The phosphazene compound (component F) represented by the above formula (1) or (2) is used as a flame retardant along with the metal hydroxide (component E). For the phosphazene compound (component F), SPR-100, SA-100 and SP-100 (each from Otsuka Chemical Co., Ltd.), FP-100 and FP-110 (each from FUSHIMI Pharmaceutical Co., Ltd.), and so on are available as commercial products. The content of phosphorus element contained in the phosphazene compound represented by the formula (1) or (2) is preferably 12% by weight or more because the flame retardant effect is exhibited even with a small amount. From the viewpoint of stability and suppression of generation of voids, use of a cyclic phosphazene oligomer represented by the formula (3) is preferred. For the cyclic phosphazene oligomer represented by the formula (3), FP-100 and FP-110 (each from FUSHIMI Pharmaceutical Co., Ltd.) and so on are available as commercial products.

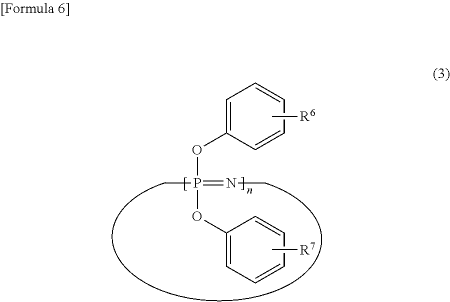

In the formula, n is an integer of 3 to 25, and R⁶ and R⁷ may be the same or independent of each other, and are each a monovalent organic group selected from the group consisting of hydrogen, a hydroxyl group, an alkyl group, an alkoxy group and a glycidyl group.

By using the above-described metal hydroxide (component E) and phosphazene compound (component F) in combination, a sheet-shaped thermosetting resin composition, which is excellent in flame retardancy while securing flexibility required for sheet sealing, can be obtained. That is, when only the metal hydroxide (component E) is used as a flame retardant, it is difficult to achieve sufficient flexibility, and when only the phosphazene compound (component F) is used as a flame retardant, it is difficult to achieve sufficient flame retardancy.

For the contents of the metal hydroxide (component E) and the phosphazene compound (component F), the total amount of both the components is 70 to 90% by weight, preferably 75 to 85% by weight, with respect to the total sheet-shaped thermosetting resin composition. That is, when the total amount is less than 70% by weight, it is difficult to achieve sufficient flame retardancy of the sheet-shaped thermosetting resin composition, and when the total amount is more than 90% by weight, tackiness of the sheet-shaped thermosetting resin composition to the lead frame may be reduced, leading to generation of voids.

The content of the phosphazene compound (component F) is preferably 10 to 30% by weight with respect to total organic components including the epoxy resin (component A), the phenol resin (component B), the elastomer (component C), the curing accelerator (component D) and the phosphazene compound (component F), each of which is contained in the sheet-shaped thermosetting resin composition. That is, when the content of the phosphazene compound (component F) is less than 10% by weight with respect to total organic components, flame retardancy of the sheet-shaped thermosetting resin composition may be deteriorated, and unevenness followability to the lead frame may also be deteriorated, leading to generation of voids. When the content is more than 30% by weight with respect to total organic components, workability may be deteriorated because tacking easily occurs on the surface of the sheet-shaped thermosetting resin composition, so that it is difficult to align the sheet-shaped thermosetting resin composition with the lead frame, or the like.

### (Other Components)

In the sheet-shaped thermosetting resin composition of this embodiment, besides the above-described components, other additives such as an inorganic filler other than the metal hydroxide (component E), which is exemplified by a silica powder, and a pigment exemplified by carbon black can be appropriately compounded as required.

The inorganic filler other than the metal hydroxide (component E) is not particularly limited, and various kinds of previously known fillers can be used. Examples thereof include a quartz glass powder, talk, a silica powder (a fused silica powder, a crystalline silica powder, etc.), an alumina powder, an aluminum nitride powder and a silicon nitride powder. They may be used alone, or used in combination of two or more thereof. Particularly, use of a silica powder is preferred in terms of costs and because the thermal linear expansion coefficient of a sealed body obtained can be decreased to reduce internal stress, and among the above-mentioned silica powders, use of a fused silica powder is especially preferred from the viewpoint of high fillability and high fluidity. Examples of the fused silica powder include a spherical fused silica powder and a crushed fused silica powder, and use of a spherical fused silica powder is especially preferred from the viewpoint of fluidity. Particularly, use of those having an average particle diameter of 0.1 to 30 μm is preferred, and use of those having an average particle diameter of 0.3 to 15 μm is especially preferred. For example, the average particle diameter can be derived by randomly extracting samples from a population and measuring the samples using a laser diffraction/scattering grain size distribution measuring device.

### (Method for Production of Sheet-Shaped Thermosetting Resin Composition)

For example, the sheet-shaped thermosetting resin composition of this embodiment can be produced in the following manner.

First, a sheet-shaped thermosetting resin composition is prepared by mixing compounding components, and the method thereof is not particularly limited as long as the compounding components are uniformly dispersed and mixed. For example, a varnish obtained by dissolving or dispersing the compounding components in an organic solvent or the like is applied and formed into a sheet shape. Alternatively, the compounding components may be directly kneaded by a kneader or the like to thereby prepare a solid resin composition, followed by extruding the solid resin composition thus obtained into a sheet shape. As the above-mentioned kneader, the kneader described in the first embodiment can be suitably used.

The varnish coating method is preferred because a sheet having a uniform thickness can be easily and conveniently obtained. More specifically, the components A to F and other additives as required are appropriately mixed in accordance with a usual method, and the mixture is uniformly dissolved or dispersed in an organic solvent to prepare a varnish. Then, the varnish is applied onto a base material of polyester or the like and dried, whereby a sheet-shaped thermosetting resin composition can be obtained. As required, a release sheet such as a polyester film may be laminated for protecting the surface of the sheet-shaped thermosetting resin composition. The release sheet is peeled off during sealing.

The organic solvent is not particularly limited, and previously known various kinds of organic solvents, for example, methyl ethyl ketone, acetone, cyclohexanone, dioxane, diethyl ketone, toluene, ethyl acetate and the like can be used. They may be used alone, or used in combination of two or more thereof. Usually, it is preferred to use the organic solvent so that the solid concentration of the varnish is 30 to 60% by weight.

The thickness of the sheet after drying the organic solvent is not particularly limited, but is usually set at preferably 5 to 100 μm, more preferably 20 to 70 μm from the viewpoint of uniformity of thickness and the amount of a residual solvent. As required, the sheet-shaped thermosetting resin composition thus obtained may be laminated to one another so as to have a desired thickness, and used. That is, the sheet-shaped thermosetting resin composition may be used in a single-layer structure, or used as a laminate formed by laminating the sheet into a multilayer structure of two or more layers.

When the sheet-shaped thermosetting resin composition of this embodiment obtained in the manner described above is used, a sealed body and a semiconductor package, each having high flame retardancy, can be easily obtained.

Then, the sheet-shaped thermosetting resin composition is bonded to the semiconductor element and the lead frame by performing flat plate pressing at a temperature of 80 to 110° C. and a pressure of 50 to 2000 kPa. At this time, the pressing time is preferably 0.5 to 5 minutes.

Further, it is preferred to perform pressing under a reduced pressure atmosphere for improving followability and adhesion of the sheet-shaped thermosetting resin composition to an uneven portion from the semiconductor element and the lead frame. The reduced-pressure degree at this time is preferably 95 to 98 kPa.

Thereafter, the sheet-shaped thermosetting resin composition is cured at a temperature of 100 to 200° C. under an atmospheric pressure to thereby obtain a sealed body. At this time, the heating time is preferably 30 to 120 minutes for causing heat curing to proceed quickly and completely.

### Other Embodiments

Sheet-shaped thermosetting resin compositions in the first pressure-bonding step and the second pressure-bonding step are not limited to the combination described above, and for example, the sheet-shaped thermosetting resin composition described in the fourth embodiment may be used in the first pressure-bonding step, and the sheet-shaped thermosetting resin composition in the first pressure-bonding step of the first embodiment may be used in the second pressure-bonding step. Alternatively, the sheet-shaped thermosetting resin composition described in the fourth embodiment may be used in both the first and second pressure-bonding steps.

In the first embodiment, the semiconductor element is used as an electronic component, and the lead frame is used as an adherend, but other elements may be used. For example, a capacitor, sensor device, a light emitting element, a vibration element or the like can be used as the electronic component, and a printed wiring board, a tape carrier or the like can be used as the adherend. Regardless of which element is used, a high level of protection can be achieved by resin-sealing while deformation and collapse of the electronic component and its peripheral structure are prevented.

### EXAMPLE

Hereinbelow, preferred example of the present invention will be described in detail in an illustrative manner. However, materials, compounding amounts and so on described in this example are not intended to limit the scope of the present invention thereto unless particularly specified. Further, the term “part(s)” refers to “part(s) by weight”.

### Example 1

First, components A to E shown below were provided.

### <Component A: Epoxy Resin Containing an Acetal Group>

Modified bisphenol A type epoxy resin (DIC Corporation, EPICLON EXA-4850-150): 6% by weight

### <Component B: Epoxy Resin>

Triphenylmethane type epoxy resin (Nippon Kayaku Co., Ltd., EPPN-501HY)

### <Component C: Phenol Resin>: 3% by Weight

Novolac type phenol resin (ARAKAWA CHEMICAL INDUSTRIES, LTD., P-200)

### <Component C: Elastomer>

Acryl-based copolymer (copolymer formed of butyl acrylate:acrylonitrile:glycidyl methacrylate=85:8:7 (% by weight); weight average molecular weight: 800,000): 27% by weight

The acryl-based copolymer was synthesized in the following manner. Butyl acrylate, acrylonitrile and glycidyl methacrylate were radically polymerized at a charge weight ratio of 85:8:7 under a nitrogen flow in methyl ethyl ketone at 70° C. for 5 hours and at 80° C. for 1 hour using 2,2′-azobisisobutyronitrile as a polymerization initiator, thereby obtaining a desired acryl-based copolymer.

### <Component D: Inorganic Filler>

Spherical fused silica powder having an average particle diameter of 0.5 μm: 60% by weight

### <Component E: Imidazole Compound>

2-phenyl-4,5-dihydroxymethylimidazole (compound represented by the formula (2), wherein in the formula (1), R¹ and R² are each a methylol group): 1% by weight

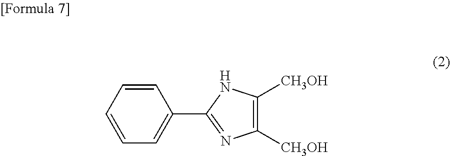

### Preparation of Sheet-Shaped Epoxy Resin Composition

Components A to E were dispersed and mixed at the ratio described above, 0.5% by weight of carbon black was further dispersed and mixed, and thereto was added methyl ethyl ketone in an amount equal to the total amount of the components, thereby preparing a varnish for coating.

Next, the varnish was applied onto the release treatment surface of a polyester film having a thickness of 38 μm (Mitsubishi Plastics, Inc., MRF-38) using a comma coater, and dried to thereby obtain a sheet-shaped thermosetting resin composition having a thickness of 50 μm.

The release treatment surface of a separately provided polyester film was laminated to the sheet-shaped thermosetting resin composition, and the laminate was wound. Thereafter, 12 sheets of the sheet-shaped thermosetting resin composition were laminated by a roll laminator while the polyester film was appropriately peeled off, thereby obtaining a sheet-shaped thermosetting resin composition having a thickness of 600 μm.

### Preparation of Sealed Body

A lead frame (length: 70 mm, width: 70 mm and thickness: 130 μm) on which four semiconductor elements (length: 5 mm, width: 5 mm and thickness: 225 μm) as electronic components were arranged and placed on die pads was provided as an adherend. Next, a frame-shaped spacer (thickness: 820 mm) having openings (length: 21 mm and width 21 mm) at four positions corresponding to the semiconductor elements, respectively, was provided, the frame-shaped spacer having a shape illustrated in FIG. 2. The frame-shaped spacer and the lead frame were superimposed on each other so that the semiconductor elements and their peripheral structures were accommodated in the openings. Then, the sheet-shaped thermosetting resin composition (cut to a length of 22 mm and a width of 22 mm) having a thickness of 600 μm, which was obtained as described above, was arranged so as to cover all the semiconductor elements on the lead frame (back surface side). The arranged sheet-shaped thermosetting resin composition was pressed at a temperature of 90° C. and a pressure of 500 kPa under a reduced pressure (98 kPa) to thereby be bonded the semiconductor elements and the lead frame. Thereafter, the pressure of pressing was released, the sheet-shaped thermosetting resin composition was heat-cured (150° C., 1 hour) to seal the semiconductor elements, and this was naturally cooled to normal temperature to perform resin-sealing of one surface of the lead frame. Further, resin-sealing of the opposite surface of the lead frame was performed using a sheet-shaped thermosetting resin composition similar to that described above, and heat curing was conducted to obtain a sealed body.

### Comparative Example 1

A sealed body was prepared in the same manner as in Example 1 except that a frame-shaped spacer was not used.

### Observation of Internal Structure of Sealed Body

The sealed body obtained from each of Example 1 and Comparative Example 1 was cut at a location including the semiconductor element using a precision cutter, and the cross section thereof was observed with DIGITAL MICROSCOPE VHX-5000 (manufactured by KEYENCE Corporation, magnification: 20 to 200). As a result, either deformation or collapse of the semiconductor element and its peripheral structure was not observed in the sealed body of Example 1, whereas it was observed that the semiconductor element was sealed in a state of being shifted from a predetermined position due to deformation of the inner lead in the sealed body of Comparative Example 1.

What is claimed is:

1. A method for production of a sealed body, comprising:
an adherend providing step of providing an adherend on which at least one electronic component is so mounted as to be displaced from a first main surface;
a frame-shaped spacer providing step of providing a frame-shaped spacer having an opening formed at a position corresponding to the electronic component;
a step of superimposing the frame-shaped spacer and the adherend so that the electronic component is accommodated in the opening;
a first pressure-bonding step of pressure-bonding a sheet-shaped thermosetting resin composition to a second main surface on a side opposite to the first main surface in a state of superimposing the frame-shaped spacer;
a frame-shaped spacer removing step of removing the frame-shaped spacer; and
a second pressure-bonding step of pressure-bonding a sheet-shaped thermosetting resin composition, which is the same as or different from the sheet-shaped thermosetting resin composition, to the first main surface so as to embed the electronic component.

2. The method for production of a sealed body according to claim 1, wherein at least one of the first pressure-bonding step and the second pressure-bonding step is performed using flat plate press processing.

3. The method for production of a sealed body according to claim 2, wherein the flat plate press processing is performed through a spacer to adjust the thickness of the sheet-shaped thermosetting resin composition.

4. The method for production of a sealed body according to claim 1, wherein at least one of the first pressure-bonding step and the second pressure-bonding step is performed under a reduced-pressure atmosphere.

5. The method for production of a sealed body according to claim 1, wherein a plurality of electronic components are mounted on the adherend, and the second pressure-bonding step is performed so as to embed the plurality of electronic components side by side.

6. A frame-shaped spacer for production of a sealed body, which is used in the method for production of a sealed body according to claim 1, and having an opening formed at a position corresponding to the electronic component.

7. A sealed body which is obtained by the method for production of a sealed body according to claim 1.

8. An electronic instrument which is obtained by dicing the sealed body according to claim 7.
